(19) United States
(12) Patent Application Publication
(10) Pub. No.: US 2023/0282656 A1
(43) Pub. Date: Sep. 7, 2023

(54) IMAGE SENSOR WITH NANOSTRUCTURE-BASED CAPACITORS

(71) Applicant: Smoltek AB, GÖTEBORG (SE)

(72) Inventors: M Shafiqul Kabir, VÄSTRA FRÖLUNDA (SE); Vincent Desmaris, GÖTEBORG (SE); Anders Johansson, ÖCKERÖ (SE); Ola Tiverman, VÄSTRA FRÖLUNDA (SE); Karl Lundahl, GÖTEBORG (SE); Rickard Andersson, GÖTEBORG (SE); Muhammad Amin Saleem, GÖTEBORG (SE); Maria Bylund, GÖTEBORG (SE); Victor Marknäs, MÖLNDAL (SE)

(21) Appl. No.: 18/009,052

(22) PCT Filed: Jun. 15, 2021
(86) PCT No.: PCT/SE2021/050582

§ 371 Date: Dec. 8, 2022

(30) Foreign Application Priority Data
Jun. 22, 2020 (SE) 2050737-2

(51) Int. Cl. H01L 27/146; H01L 21/3105

(52) U.S. Cl. CPC H01L 27/14609; H01L 27/14636; H01L 27/14683; H01L 21/31053; H01L 28/91

(57) ABSTRACT

An image sensor comprising an image sensor layer having a plurality of image sensor layer contact pads; and a plurality of photo-sensitive elements, each being coupled to a respective image sensor layer contact pad; and a capacitor layer having: a plurality of first capacitor contact structures, each being constituted by a capacitor layer top contact pad bonded to a respective image sensor layer contact pad of the image sensor layer; a plurality of second capacitor contact structures; and a plurality of capacitors, embedded in a first dielectric material, each capacitor including at least one electrically conductive vertical nanostructure electrically conductively connected to one of a respective first capacitor contact structure and a respective second capacitor contact structure, and conductively separated from the other one of the respective first capacitor contact structure and the respective second capacitor contact structure by a layer of a second dielectric material.

### FIELD OF THE INVENTION

The present invention relates to an image sensor comprising an image sensor layer and a capacitor layer.

### BACKGROUND OF THE INVENTION

Image sensors are in wide use in all kinds of electronic devices. For example, there is a recent trend for equipping mobile phones with more and more cameras. At the same time, requirements on image quality increases.

Image sensors generally include photo-sensitive elements, such as CCD sensors or photodiodes. The photo-sensitive element (or elements) in an image sensor pixel may generate a charge that is dependent on the amount of light that is hitting the photo-sensitive element. By measuring the amount of charge generated, the amount of light hitting the image sensor pixel can be determined.

According to one approach using photo-diodes (which may be part of corresponding transistors), photo-currents from pixels may be read out row by row, using a so-called rolling shutter scheme. This approach, however, has inherent problems with image distortion when imaging moving objects.

At least for demanding applications, such as in the industrial sector, the rolling shutter scheme is therefore increasingly replaced by a so-called global shutter scheme, according to which the photo-currents from all pixels in the image sensor are read out simultaneously. Although not suffering from the above-described kind of image distortion of the rolling shutter scheme, the global shutter scheme practically requires a charge storage capacitor per pixel in the image sensor.

The charge storage capability of the charge storage capacitors limits the dynamic range in the pixel. Once the charge storage capacitor of an image sensor pixel is “full”, that pixel is saturated. The obvious solution is to increase the size of the charge storage capacitors, which, however, goes against the desire for higher resolution images and ever smaller and cheaper image sensors.

Different solutions to this problem have been presented, in which the image sensor is provided as a layered image sensor with an image sensor layer including the photo-sensitive elements, and an auxiliary layer including charge storage capacitors. The image sensor layer and the auxiliary layer are bonded together to form the image sensor. Variations of this approach are described in, for example, US 2010/0238334, US 2017/0170224, and US 2017/0345854. Although having advantages over image sensors in which the photo-sensitive element and charge storage capacitor of a pixel are formed in the same layer, there is still room for improvement in relation to the solutions described in these documents.

It would thus be desirable to provide an improved image sensor, in particular an image sensor that provides for an improved relation between image resolution and dynamic range and/or more cost-efficient production.

### SUMMARY

It is an object of the present invention to provide an improved image sensor, in particular an image sensor that provides for an improved relation between image resolution and dynamic range, and/or more cost-efficient production.

According to a first aspect of the present invention, it is therefore provided an image sensor comprising: an image sensor layer having: a plurality of image sensor layer contact pads; and a plurality of photo-sensitive elements, each being coupled to a respective image sensor layer contact pad in the plurality of image sensor layer contact pads; and a capacitor layer having: a plurality of first capacitor contact structures, each being constituted by a capacitor layer top contact pad bonded to a respective image sensor layer contact pad in the plurality of image sensor layer contact pads of the image sensor layer; a plurality of second capacitor contact structures; and a plurality of capacitors, embedded in a first dielectric material, each capacitor including at least one electrically conductive vertical nanostructure, the at least one electrically conductive vertical nanostructure being electrically conductively connected to one of a respective first capacitor contact structure and a respective second capacitor contact structure, and conductively separated from the other one of the respective first capacitor contact structure and the respective second capacitor contact structure by a layer of a second dielectric material, different from the first dielectric material, conformally coating the at least one electrically conductive vertical nanostructure.

By “vertical” nanostructure should be understood a nanostructure that is arranged perpendicular to a plane parallel to the capacitor layer (and thus to the image sensor, which is a layered structure).

An electrically conductive nanostructure may be formed from an electrically conductive material, or it may be formed from an electrically insulating material and conformally coated with a conductive material, such as a metal.

The present invention is based on the realization that a favorable combination of high dynamic range, high resolution and cost-efficient production for an image sensor can be achieved by providing a capacitor layer with nanostructure-based capacitors embedded in a dielectric material. In particular, the present inventors have found that the use of electrically conductive vertical nanostructures provides for an exceptionally high capacitance per surface area of the capacitor layer, and that capacitors including such electrically conductive vertical nanostructures can be embedded in a dielectric material, which provides for cost-efficient production. In particular, a capacitor layer in which capacitors are embedded in a dielectric material can be made considerably less brittle than a capacitor layer in which the capacitors are formed by etching an inherently brittle semiconductor material, such as silicon. Examples of such more brittle capacitor layers may include capacitor layers in which the capacitors are so-called deep trench type capacitors (TSC) and similar.

According to embodiments, the first dielectric material may have a first relative permittivity, and the second dielectric material may have a second relative permittivity that is at least twice the first relative permittivity.

Hereby, a high capacitance density is provided for, while reducing the parasitic capacitances and/or reducing the risk of cross-talk between capacitors of different image sensor pixels.

According to one non-limiting example, the first relative permittivity may be lower than 3.9, preferably lower than 3.5, and the second relative permittivity may be higher than 7.8, preferably higher than 20.

In embodiments, each capacitor in the plurality of capacitors may be separated from neighboring capacitors in the plurality of capacitors by the first dielectric material. Advantageously, the capacitors may be completely separated from each other by the first dielectric material, to effectively reduce parasitic capacitances and/or cross-talk.

The at least one electrically conductive vertical nanostructure included in each capacitor in the plurality of capacitors has a height and a maximum width, and a ratio between the height and the maximum width may advantageously be at least 5 times.

For instance, the height may be at least 1 μm, and the maximum width may be less than 200 nm.

The “height” of the nanostructure is its length in the vertical direction (perpendicular to a plane parallel to the capacitor layer), and the “maximum width” is the greatest lateral extension (in a plane parallel to the capacitor layer) of the nanostructure. For a trench type capacitor in a prior art device, the maximum width would be the length of the trench.

According to various embodiments, the electrically conductive vertical nanostructures in the capacitor layer may be grown nanostructures. The use of grown nanostructures allows extensive tailoring of the properties of the nanostructures. For instance, the growth conditions may be selected to achieve a morphology giving a large surface area of each nanostructure, which may in turn increase the charge storage capacity of the capacitors in the capacitor layer.

The nanostructures may, for example, be nanowires, nano-horns, nanotubes, nano-walls, crystalline nanostructures, or amorphous nanostructures.

According to various embodiments, the nanostructures may advantageously be carbon nanostructures, such as carbon nanofibers, carbon nanotubes or carbide-derived carbon nanostructures.

According to embodiments, each capacitor in the plurality of capacitors may comprise a plurality of electrically conductive vertical nanostructures, each being electrically conductively connected to one of the respective first capacitor contact structure and the respective second capacitor contact structure, and conductively separated from the other one of the respective first capacitor contact structure and the respective second capacitor contact structure by the layer of the second dielectric material.

In various embodiments, the capacitor layer may comprise a plurality of capacitor layer bottom contact pads at a bottom of the capacitor layer; and each second capacitor contact structure in the plurality of second capacitor contact structures may constitute a respective capacitor layer bottom contact pad in the plurality of capacitor layer bottom contact pads.

In embodiments, the image sensor may additionally comprise a signal processing layer having: a plurality of signal processing layer contact pads, each being bonded to a respective capacitor layer bottom contact pad in the plurality of capacitor layer bottom contact pads; and signal processing circuitry coupled to the signal processing layer contact pads.

In embodiments, the image sensor may additionally comprise additional layers having: a plurality of contact pads, computing processor, memory, sensors, RF for wireless communications etc. each being coupled to the signal processing layer contact pads.

The image sensor according to embodiments of the present invention may be included in an electronic device further comprising processing circuitry coupled to the image sensor, for performing operations on image data acquired from the image sensor.

In embodiments according to the present invention, the different layers may be bonded utilizing any standard bonding techniques known in the art, e.g. die bonding, hybrid bonding, metal to metal bonding, wafer level bonding, wafer to wafer or die to die or die to wafer level bonding etc. without deviating from the scope of the present invention.

According to a second aspect of the present invention, there is provided a method of manufacturing a capacitor layer for an image sensor, comprising the steps of: providing a substrate having a first plurality of discrete conductive material islands thereon; providing, on each discrete conductive material island in the first plurality of discrete conductive material islands, at least one electrically conductive nanostructure in such a way that the electrically conductive nanostructure extends substantially vertically from the discrete conductive material island and a first end of the electrically conductive nanostructure is in electrically conductive contact with the discrete conductive material island; applying a conformal dielectric layer on the electrically conductive nanostructures provided on the discrete conductive material islands; applying a conductive material layer on the conformal dielectric layer, to form a plurality of capacitors, each including at least one electrically conductive nanostructure, the conformal dielectric layer and the conductive material layer; embedding the plurality of capacitors in a dielectric material; forming a second plurality of discrete conductive material islands, in such a way that each discrete conductive material island in the second plurality of discrete conductive material islands makes electrically conductive contact with the conductive material layer on the at least one electrically conductive nanostructure provided on a respective one of the discrete conductive material islands in the first plurality of discrete conductive material islands; and removing the substrate.

In summary, the present invention thus relates to an image sensor comprising an image sensor layer having a plurality of image sensor layer contact pads; and a plurality of photo-sensitive elements, each being coupled to a respective image sensor layer contact pad; and a capacitor layer having: a plurality of first capacitor contact structures, each being constituted by a capacitor layer top contact pad bonded to a respective image sensor layer contact pad of the image sensor layer; a plurality of second capacitor contact structures; and a plurality of capacitors, embedded in a first dielectric material, each capacitor including at least one electrically conductive vertical nanostructure electrically conductively connected to one of a respective first capacitor contact structure and a respective second capacitor contact structure, and conductively separated from the other one of the respective first capacitor contact structure and the respective second capacitor contact structure by a layer of a second dielectric material.

### BRIEF DESCRIPTION OF THE DRAWINGS

These and other aspects of the present invention will now be described in more detail, with reference to the appended drawings showing example embodiments of the invention, wherein:

FIG. 1 is an illustration of an exemplary electronic device comprising an image sensor according to an embodiment of the present invention, in the form of a mobile phone;

FIG. 2 schematically shows an image sensor comprised in the electronic device in FIG. 1;

FIGS. 3A-B are schematic illustrations of a first embodiment of the image sensor in FIG. 2;

FIGS. 4A-B are schematic illustrations of a second embodiment of the image sensor in FIG. 2;

FIGS. 5A-C are schematic illustrations of a first set of exemplary capacitor configuration;

FIG. 6 is a flow-chart schematically illustrating a method according to a first embodiment of the present invention;

FIGS. 7A-C are schematic illustrations of a second set of exemplary capacitor configuration; and

FIG. 8 is a flow-chart schematically illustrating a method according to a second embodiment of the present invention.

### DETAILED DESCRIPTION OF EXAMPLE EMBODIMENTS

In the present detailed description, various embodiments of the image sensor according to the present invention are mainly described in the context of an exemplary electronic device, in the form of a mobile phone. It should be noted that the use of the image sensor according to embodiments of the invention is in no way limited to this kind of electronic device, but may be highly useful for other applications, such as industrial applications.

It should be understood that the image sensor according to various embodiments of the present invention may equally well be included in, and useful for, other types of electronic devices, such as, for example: an AR, VR, MR; an entertainment unit; a navigation device; a communications device; a fixed location data unit; a mobile location data unit; a global positioning system (GPS) device; a smart watch; a wearable computing device; a digital camera; a CCD camera; a tablet; an ADAS; a server; a computer; a portable computer; a mobile computing device; a battery charger; a USB device; a desktop computer; a personal digital assistant (PDA); a monitor; a computer monitor; a television; a tuner; a radio; a satellite radio; a music player; a digital music player; a portable music player; a digital video player; an automobile; an electric vehicle; a vehicle component; avionics systems; a drone; and a multicopter.

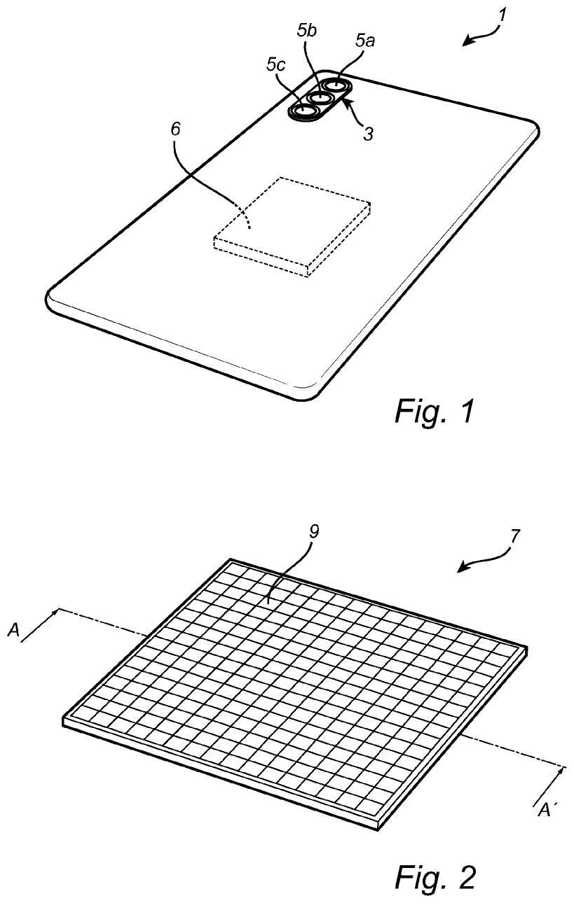

FIG. 1 schematically shows an example electronic device, in the form of a mobile phone 1 having a camera module 3 with three cameras 5a-c arranged on the backside of the mobile phone 1. One or more of the cameras 5a-c may include an image sensor according to embodiments of the present invention. The mobile phone 1 also includes processing circuitry for controlling operation of the mobile phone 1. As is indicated in FIG. 1, the processing circuitry may include separate circuitry, here in the form of a schematic camera controller 6, for controlling operation of the cameras 5a-c. Instead of being provided as a separate camera controller 6, the circuitry for controlling operation of the cameras 5a-c may be an integral part of processing circuitry configured to additionally control other parts of the mobile phone 1.

FIG. 2 is a schematic illustration of an image sensor 7 according to embodiments of the present invention. As is indicated in FIG. 2, the image sensor 7 comprises a plurality of pixels 9 arranged in an array. As is well known to those skilled in the art, the image sensor 7 in FIG. 2 may be packaged in different ways to form a camera module for connection to the camera controller 6 in FIG. 1 or other processing circuitry. For the sake of simplicity of illustration, the schematic image sensor 7 in FIG. 2 has far fewer pixels 9 than a real image sensor.

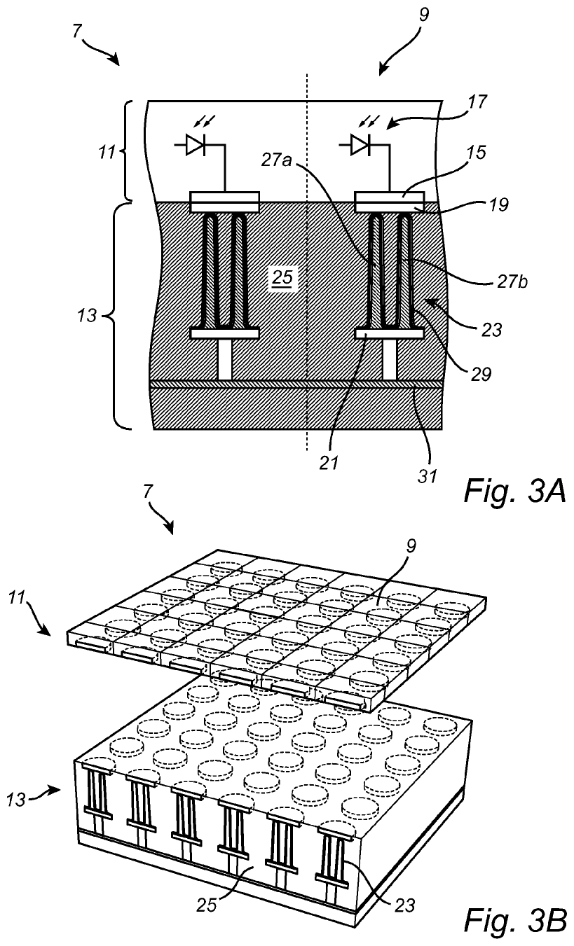

FIGS. 3A-B are schematic illustrations of a first embodiment of the image sensor 7 in FIG. 2. Referring first to FIG. 3A, which is a cross-section view of the image sensor 7, of the section taken along the line A-A′ in FIG. 2, the image sensor 7 according to this first embodiment comprises an image sensor layer 11 and a capacitor layer 13. The image sensor layer 11 comprises a plurality of image sensor layer contact pads 15 (only indicated with a reference numeral for one of the pixels 9 of the image sensor 7 to avoid cluttering the drawings) and a plurality of photo-sensitive elements 17, each being coupled to a respective image sensor layer contact pad 15.

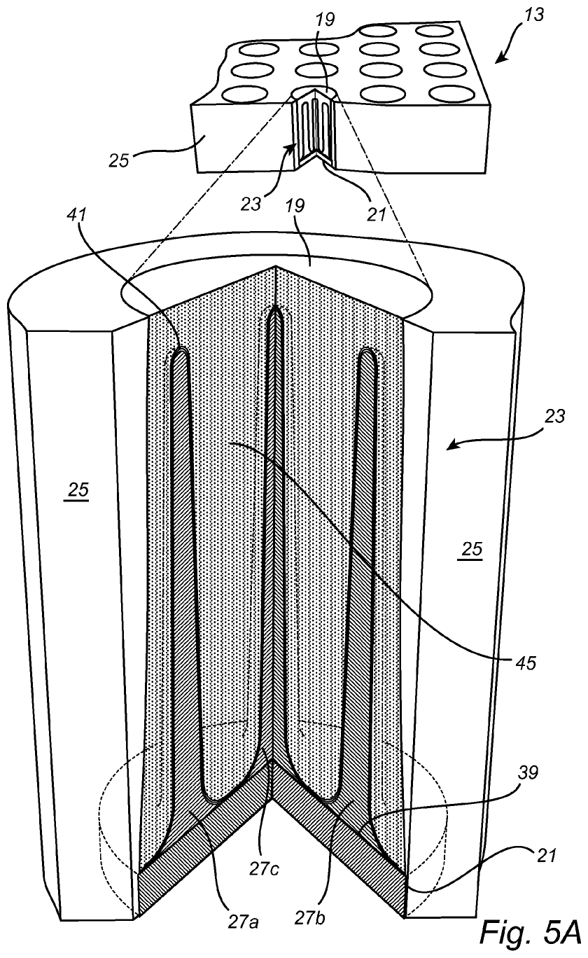

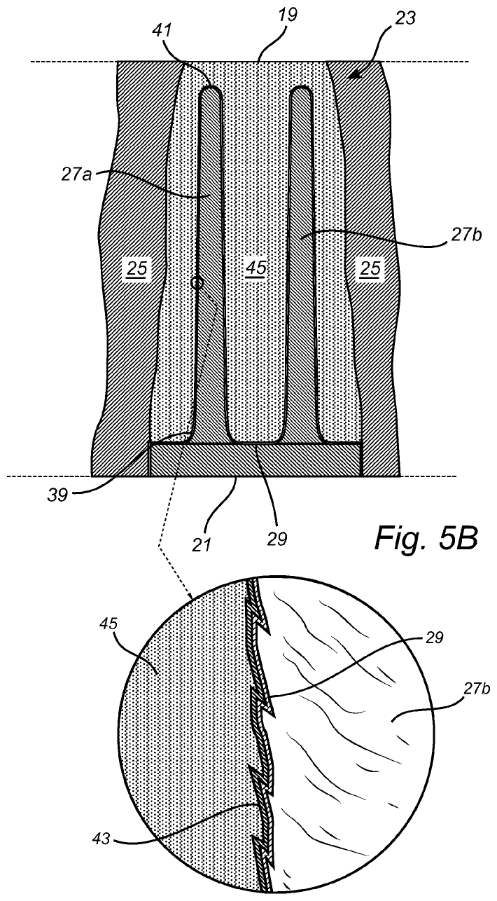

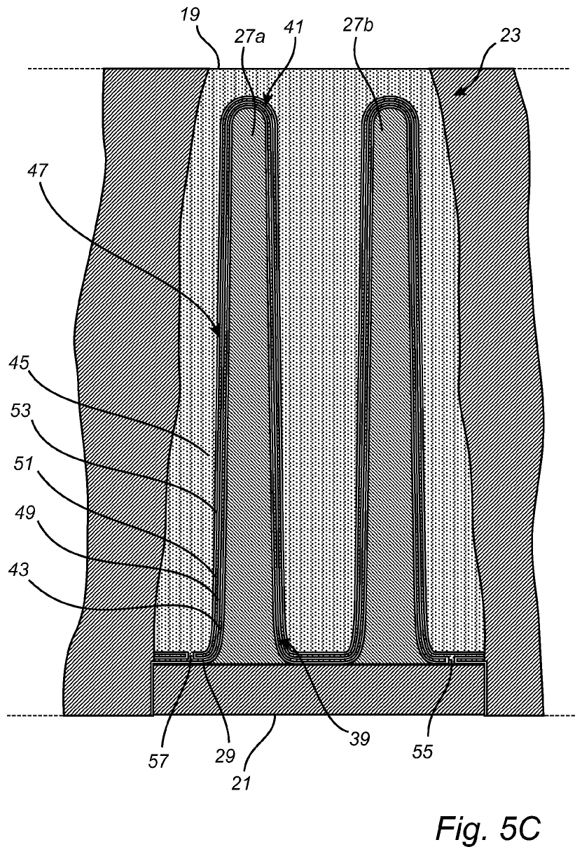

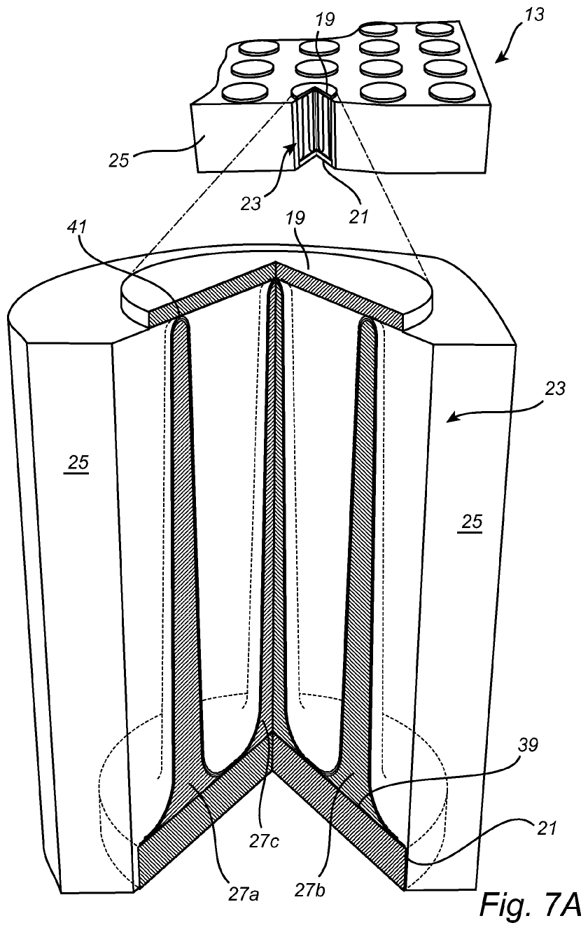

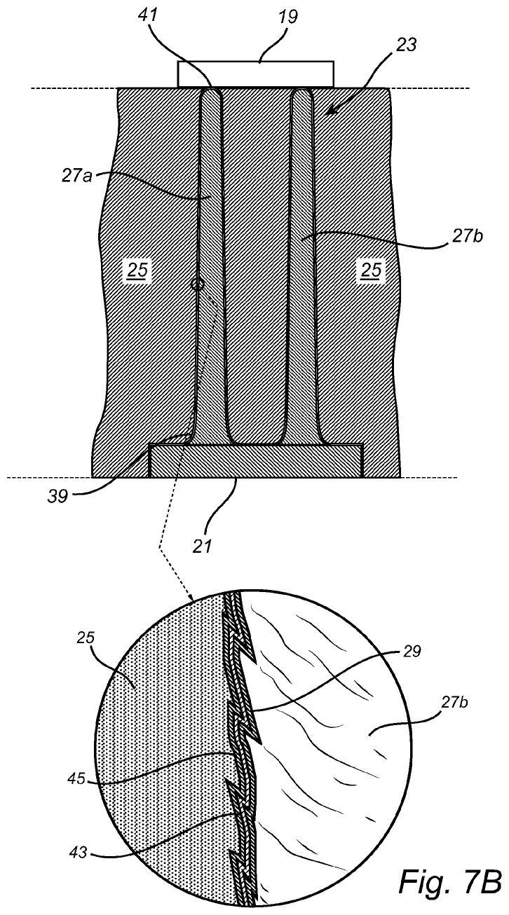

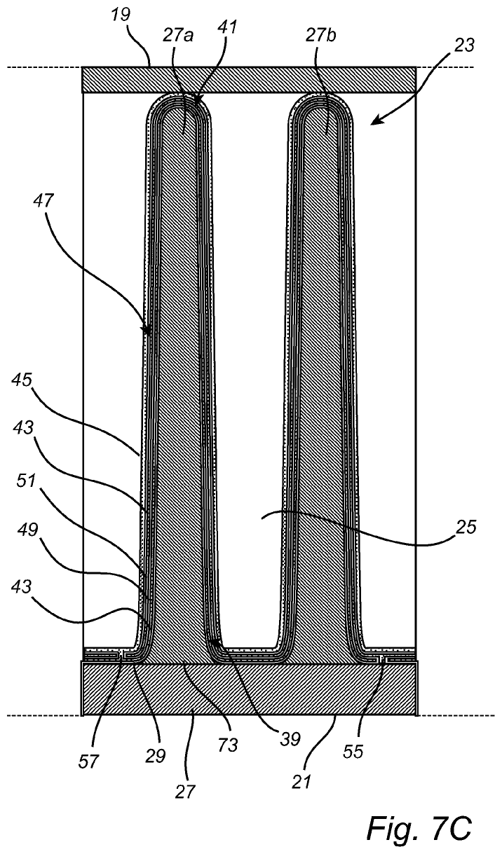

With continued reference to FIG. 3A, the capacitor layer 13 comprises a plurality of first capacitor contact structures, each being constituted by a capacitor layer top contact pad 19, a plurality of second capacitor contact structures 21, and a plurality of capacitors 23. As is schematically indicated in FIG. 3A, each capacitor layer top contact pad 19 is bonded to a respective image sensor layer contact pad 15, through any suitable bonding technique known to the skilled person. Each capacitor 23 in the plurality of capacitors is embedded in a first dielectric material 25, and each capacitor 23 comprises at least one electrically conductive vertical nanostructure 27a-b. In the example capacitor configuration in FIG. 3A, the electrically conductive vertical nanostructures 27a-b are electrically conductively connected to the second capacitor contact structure 21, and conductively separated from the first capacitor contact structure (the capacitor layer top contact pad 19) by a layer 29 of a second dielectric material conformally coating the vertical nanostructures 27a-b. The second dielectric material is different from the first dielectric material 25, that embeds the capacitors 23 in the capacitor layer 13. Alternatively, the vertical nanostructures 27a-b may be electrically conductively connected to the first capacitor contact structure (the capacitor layer top contact pad 19), and conductively separated from the second capacitor contact structure 21. More detailed example configurations of the capacitors 23 will be described further below with reference to FIGS. 5A-C and FIGS. 7A-C. In the first example embodiment in FIGS. 3A-B, the second capacitor contact structure 21 may be connected to routing or switching circuitry 31 comprised in the capacitor layer 13.

As is better seen in FIG. 3B, which is a simplified exploded perspective view of the image sensor 7 in FIG. 2, the capacitors 23 in the capacitor layer 13 may be completely separated from each other by the first dielectric material embedding the capacitors 23. As can also be understood from FIG. 3B, the image sensor layer 11 and the capacitor layer 13 may suitably be provided as separate dies that are bonded together using die bonding techniques. Hereby, the image sensor layer 11 and the capacitor layer 13 can each be manufactured using dedicated and suitable materials and processes. By embedding the capacitors 23 in a dielectric material (the first dielectric material 25) which may, for example, be a polymer or one or several standard dielectric materials, the capacitor layer 13 can be made relatively cost-efficient and durable. In particular, the capacitor layer may be considerably less brittle than a structure formed based on a semiconductor substrate, especially if such a semiconductor substrate is perforated by a large number of vias.

To provide for reduced parasitic capacitances and/or a low degree of cross-talk (unwanted capacitive coupling) between neighboring pixels, the first dielectric material 25 may advantageously be a low-k dielectric, preferably a polymer. For a high capacitance density (and high capacitance) for each capacitor 23, the second dielectric in the layer 29 conformally coating the vertical nanostructures 27a-b may advantageously be a high-k dielectric.

To provide for the desired combination of a high resolution and good dynamic range for the image sensor 7, the capacitance density of each capacitor 23 may advantageously be at least 200 fF/μm², where the relevant area is the foot-print area of the capacitor 23. For the example configuration in FIGS. 3A-B, the relevant area may be the area of the capacitor layer top contact pad 19 and/or the area of the second capacitor contact structure 21. Through a capacitor configuration capable of providing such a high capacitance density, even very small pixels can have a sufficiently large charge storage capacity, such as at least 200 fF per pixel 9.

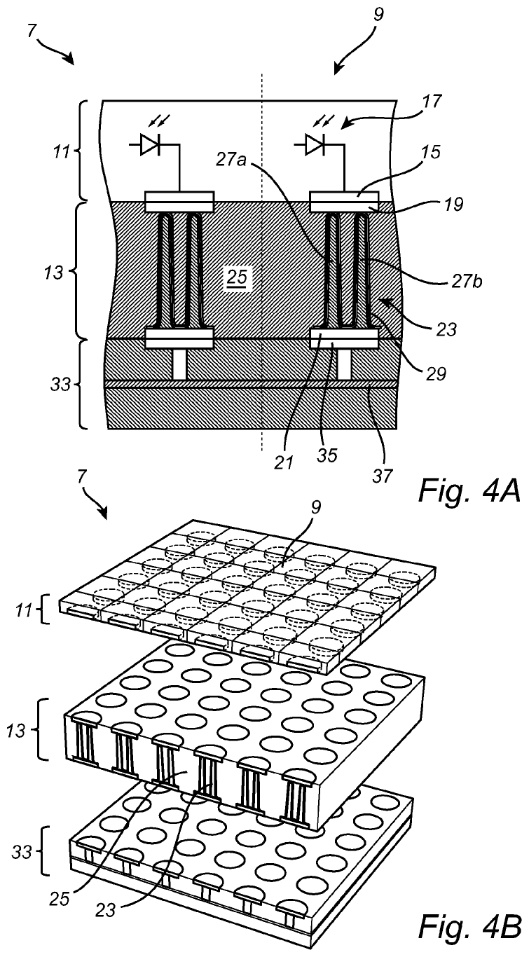

FIGS. 4A-B are schematic illustrations of a second embodiment of the image sensor 7 in FIG. 2. Referring first to FIG. 4A, which is a cross-section view of the image sensor 7, of the section taken along the line A-A′ in FIG. 1, the image sensor 7 according to this second embodiment comprises an image sensor layer 11, a capacitor layer 13, and a signal processing layer 33.

As is schematically indicated in FIG. 4A, the signal processing layer 33 comprises a plurality of signal processing layer contact pads 35 and signal processing circuitry 37 coupled to the signal processing layer contact pads 35.

Even though not explicitly shown in the FIG. 4A, the present invention contemplates that there may be more layers like layer 33 to accommodate for example memory, processors, sensors, RF-circuitry etc. to build up a stacked complex system.

The capacitor layer 13 of the second embodiment of the image sensor 7 in FIGS. 4A-B differs from that of the first embodiment described above with reference to FIGS. 3A-B in that the each second capacitor contact structure 21 in the plurality of second capacitor contact structures constitutes a respective capacitor layer bottom contact pad.

Each signal processing layer contact pad 35 of the signal processing layer 33 is bonded to a respective capacitor layer bottom contact pad 21 of the capacitor layer 13.

Although this is not explicitly shown in the figures, the image sensor 7 according to embodiments may include various additional structures, such as microlenses, color filters, thin-film photo detectors (TFPD), etc, in manners well-known to those skilled in the art of image sensors.

FIGS. 5A-C are schematic illustrations of a first set of exemplary capacitor configurations. FIG. 5A is an enlarged cut-out portion of the capacitor layer 13 (or partial capacitor layer excluding routing or switching circuitry where applicable) showing a perspective view of a capacitor 23. The example capacitor 23 in FIG. 5A has three electrically conductive vertical nanostructures 27a-c, each having a first end 39 and a second end 41, here shown for one of the vertical nanostructures 27a only. Each of the vertical and elongated nanostructures of the capacitor 23 extends between the first end 39 and the second end 41. As can be seen in FIG. 5A, each of the nanostructures 27a-c can fit inside a cylinder with a diameter and a height. An aspect ratio of each nanostructure 27a-c can be defined as a ratio between the height of the cylinder and the diameter of the cylinder. For the nanostructures 27a-c in the capacitors 23 comprised in the image sensor 7 according to embodiments of the present invention, the aspect ratio may be at least 5. According to example embodiments, the height may be at least 1 μm and the diameter may be less than 200 nm. It should, however, be noted that other nanostructure dimensions are possible and may be suitable.

Referring to FIG. 5B, which is a cross-section view of a first embodiment of the capacitor 23 in FIG. 5A through two of the vertical nanostructures 27a-b comprised in the capacitor 23, and the enlargement of a portion thereof, each capacitor 23 comprises a first capacitor electrode constituted by the electrically conductive vertical nanostructures 27a-c, and a second capacitor electrode conductively separated from the nanostructures 27a-c by the above-mentioned conformal dielectric layer 29. In the first example configuration of FIG. 5B, the second capacitor electrode includes a first conductive layer 43 conformally coating the conformal dielectric layer 29 and a second conductive layer 45 on the first conductive layer 43, which fills the space between neighboring nanostructures 27a-c and constitutes the first capacitor contact structure/capacitor layer top contact pad 19.

The first end 39 of each nanostructure 27a-c is electrically conductively connected to the second capacitor contact structure 21, and the first capacitor structure 19 is arranged adjacent to the second end 41 of each nanostructure 27a-c.

Turning now to FIG. 5C, a layered stack 47 of alternating conduction-controlling layers and electrode layers coats the conformal dielectric layer 29 and includes at least a first odd-numbered (first) electrode layer 43 at a bottom of the layered stack 47, a first odd-numbered (first) conduction-controlling layer 49 directly on the first odd-numbered electrode layer 43, and a first even-numbered (second) electrode layer 51 directly on the first odd-numbered conduction-controlling layer 49. In the example configuration of FIG. 5C, the layered stack 47 additionally includes a first even-numbered (second) conduction-controlling layer 53, and a second odd-numbered (third) electrode layer 45. In the example configuration of FIG. 5C, the third electrode layer 45 is the topmost odd-numbered electrode layer in the layered stack 47, and as can be seen in FIG. 5C, this electrode layer 45 fills the space between neighboring nanostructures 27a-c and constitutes the first capacitor contact structure/capacitor layer top contact pad 19.

Each even-numbered electrode layer (the second electrode layer 51) in the layered stack 47 is electrically conductively connected to the second capacitor contact structure 21, and each odd-numbered electrode layer (the first electrode layer 43 and the third electrode layer 45) in the layered stack 47 is electrically conductively connected to any other odd-numbered electrode layer in the layered stack (to each other), and thus also to the first capacitor contact structure/capacitor layer top contact pad 19. In the example configuration of FIG. 5C, the second electrode layer 51 and the second capacitor contact structure 21 are connected together by a first interconnect 55, and the first electrode layer 43 and the third electrode layer 45 are connected together by a second interconnect 57. In the example configuration of FIG. 5C, the space between the nanostructures 27a-c is filled with the topmost electrode layer 45, which is then planarized to form the first capacitor contact structure/capacitor layer top contact pad 19.

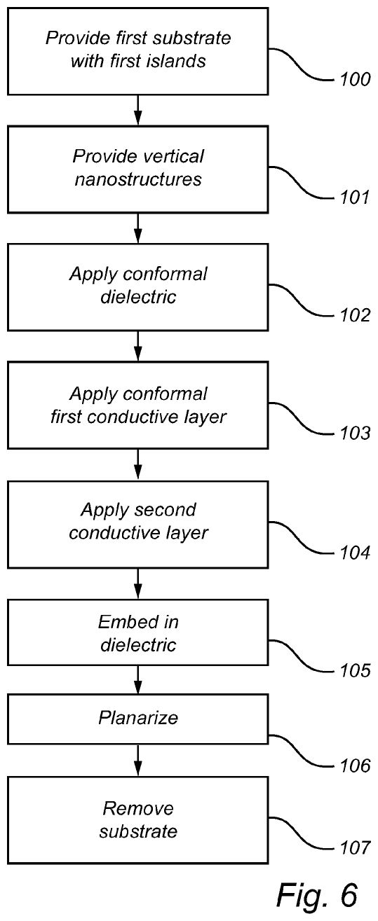

FIG. 6 is a flow-chart schematically illustrating a method according to a first embodiment of the present invention, for manufacturing a capacitor layer 13 including capacitors 23 with the first exemplary capacitor configuration described above with reference to FIGS. 5A-C.

In a first step 100, a substrate is provided. The substrate, which may for example be a glass, silicon, or plastic substrate or any other substrate used and known by the industry, has a first plurality of discrete conductive material islands provided thereon. Between the substrate and the discrete conductive material islands, there may be a so-called sacrificial layer. The discrete conductive material islands, which may advantageously be metal islands, may constitute the second capacitor contact structure 21 in FIGS. 5A-C.

In the subsequent step 101, at least one electrically conductive nanostructure 27a-c is provided in such a way that the at least one nanostructure 27a-c extends substantially vertically from the discrete conductive material island 21 and a first end 39 of the electrically conductive nanostructure 27a-c is in electrically conductive contact with the discrete conductive material island 21. Advantageously, the at least one nanostructure may be grown from each discrete conductive material island 21, using, per se, known techniques for growing vertical nanostructures.

Thereafter, in step 102, the vertical nanostructures 27a-c, and the portions of the conductive material island 21 left uncovered by the nanostructures 27a-c, may be conformally coated by a layer 29 of a second dielectric material. As was explained further above, the dielectric material of the conformal layer 29 may advantageously be made of a so-called high-k dielectric. The high k-dielectric materials may e.g. be HfOx, TiOx, TaOx, STO, Barium titanate, PZT, or other well-known high k dielectrics. Alternatively, the dielectric can be polymer based e.g. polypropylene, polystyrene, poly(p-xylylene), parylene etc.. Other well-known dielectric materials, such as SiOx or SiNx, etc may also be used as the dielectric layer 29. This dielectric layer 29 may be deposited using any known method suitable for making conformal layers, such as for example via vapor deposition, thermal processes, atomic layer deposition (ALD), etc. In various embodiments it may be advantageous to use more than one dielectric layer or dissimilar dielectric materials with different dielectric constant or different thicknesses of dielectric materials to control the effective dielectric constant or influence the breakdown voltage or the combination of them to control the dielectric film properties.

Advantageously, the dielectric material layer 29 is coated uniformly with atomic uniformity over the nanostructures 27a-c such that the dielectric layer covers the entirety of the nanostructures 27a-c so that the leakage current of the capacitor 23 is minimized. Another advantage of providing the conformal dielectric layer 29 with atomic uniformity is that such a layer 29 can conform to the surface irregularities of the conductive nanostructures 27a-c, which may be introduced during growth of the nanostructures. This provides for an increased total electrode surface area of the capacitor 23, which in turn provides for a higher capacitance density.

In the next step 103, a first conductive material layer 43, or the layered stack 47 in FIG. 5C, is applied as a conformal coating directly on the conformal dielectric layer 29. This first conductive material layer 43, which may be referred to as an adhesion metal layer, may advantageously be formed using ALD, and an example of a suitable material for the first conductive material layer 43 may be Ti, or TiN.

On top of the first conductive material layer 43, a second conductive material layer 45 is formed in step 104. This second conductive material layer 45 may, for example, include a so-called seed metal layer conformally coated on the first conductive material layer 43. Such a seed metal layer may, for example, be made of Al, Cu or any other suitable seed metal materials. When such a seed metal layer is used, additional metal may be deposited using, for example, a chemical method such as electroplating, electroless plating or any other method known in the art. As is schematically indicated in FIGS. 5A-C, the second conductive material layer 45 may advantageously fill the spaces between the nanostructures 27a-c, to thereby form a second plurality of discrete conductive material islands.

In the subsequent step 105, the capacitors 23 are embedded in a dielectric material 25. This dielectric material 25 may, as was mentioned further above, advantageously be a low-k dielectric. For example, suitable spin-on polymers, such as polyimide or BCB or spin on glass, or SiOx or SiNx may be used.

Thereafter, in step 106, the dielectric material 25 embedding the capacitors 23 is planarized at least until the second conductive material layer is exposed, to thereby form the first capacitor contact structures/capacitor layer top contact pads 19. Any suitable plasma treatment, dry chemistry, wet chemistry, or other planarization method, such as CMP, known in the art can be used for planarization.

Finally, in step 107, the substrate is removed, for example by selectively removing the sacrificial layer when such a layer is present on the substrate or polishing the substrate if needed when such sacrificial layer is not present.

FIGS. 7A-C are schematic illustrations of a second set of exemplary capacitor configurations. FIG. 7A is an enlarged cut-out portion of the capacitor layer 13 (or partial capacitor layer excluding routing or switching circuitry where applicable) showing a perspective view of a capacitor 23.

Referring to FIG. 7B, which is a cross-section view of the capacitor 23 in FIG. 7A through two of the vertical nanostructures 27a-b comprised in the capacitor 23, and the enlargement of a portion thereof, each capacitor 23 comprises a first capacitor electrode constituted by the electrically conductive vertical nanostructures 27a-c, and a second capacitor electrode conductively separated from the nanostructures 27a-c by the above-mentioned conformal dielectric layer 29. In the second set of example configurations of FIGS. 7A-C, the second capacitor electrode includes a first conductive layer 43 conformally coating the conformal dielectric layer 29 and a second conductive layer 45, which only partly fills the space between neighboring nanostructures 27a-c. As is schematically shown in FIG. 7b, the first dielectric material 25 occupies the space between the neighboring nanostructures 27a-c not filled up by the second conductive layer 45. On top of a planarized surface, the first capacitor contact structures/capacitor layer top contact pads 19 are arranged to make electrically conductive contact with the second conductive layer 45 at the second end 41 of the nanostructures 27a-c. It may be advantageous to have the first dielectric layer 25 and the top contact 19 forms a planar configuration.

FIG. 7C schematically shows a configuration with a layered stack 47 as described above with reference to FIG. 5C, with the main difference being that the space between the nanostructures 27a-c is filled by the first dielectric material 25.

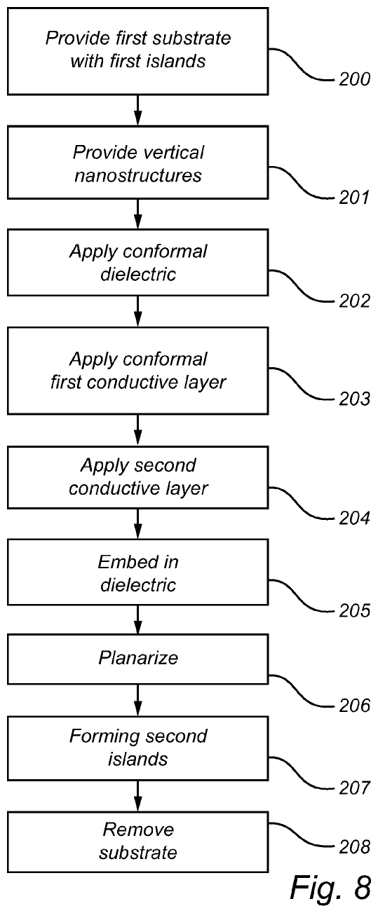

FIG. 8 is a flow-chart schematically illustrating a method according to a second embodiment of the present invention, for manufacturing a capacitor layer 13 including capacitors 23 with the second set of exemplary capacitor configurations described above with reference to FIGS. 7A-C.

Steps 200 to 206 of the method according to the second embodiment substantially correspond to steps 100 to 106, respectively, according to the first embodiment described above with reference to FIG. 6, with the potential exception that the second conductive material layer 45 may only partly fill the space between neighboring vertical nanostructures 27a-c. Step 208 correspond to step 107. Between step 206 and step 208, a step 207 of forming a second plurality of discrete conductive material islands is carried out, for example by photolithography. The second plurality of discrete conductive material islands may constitute the first capacitor contact structures/capacitor layer top contact pads 19. Further planarization scheme may be carried out so that first dielectric layer 25 and the top contact 19 forms a planar configuration.

In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. An image sensor comprising:
an image sensor layer having:
a plurality of image sensor layer contact pads; and
a plurality of photo-sensitive elements, each being coupled to a respective image sensor layer contact pad in the plurality of image sensor layer contact pads; and
a capacitor layer having:
a plurality of first capacitor contact structures, each being constituted by a capacitor layer top contact pad bonded to a respective image sensor layer contact pad in the plurality of image sensor layer contact pads of the image sensor layer;
a plurality of second capacitor contact structures; and
a plurality of capacitors, embedded in a first dielectric material, each capacitor including at least one electrically conductive vertical nanostructure, the at least one electrically conductive vertical nanostructure being electrically conductively connected to one of a respective first capacitor contact structure and a respective second capacitor contact structure, and conductively separated from the other one of the respective first capacitor contact structure and the respective second capacitor contact structure by a layer of a second dielectric material, different from the first dielectric material, conformally coating the at least one electrically conductive vertical nanostructure.

2. The image sensor according to claim 1, wherein the first dielectric material has a first relative permittivity, and the second dielectric material has a second relative permittivity that is at least twice the first relative permittivity.

3. The image sensor according to claim 1, wherein each capacitor in the plurality of capacitors is separated from neighboring capacitors in the plurality of capacitors by the first dielectric material.

4. The image sensor according to claim 1, wherein the at least one electrically conductive vertical nanostructure included in each capacitor in the plurality of capacitors has a height and a maximum width, a ratio between the height and the maximum width being at least 5 times.

5. The image sensor according to claim 1, wherein each capacitor in the plurality of capacitors comprises:
a first capacitor electrode constituted by the at least one electrically conductive vertical nanostructure; and
a second capacitor electrode comprising a conductive layer conformally coating the layer of the second dielectric material.

6. The image sensor according to claim 5, wherein the second capacitor electrode is conductively connected to the other one of the respective first capacitor contact structure and the respective second capacitor contact structure.

7. The image sensor according to claim 6, wherein, in each capacitor in the plurality of capacitors, a first end of the at least one electrically conductive vertical nanostructure is electrically conductively connected to the one of the respective first capacitor contact structure and the respective second capacitor contact structure.

8. The image sensor according to claim 7, wherein, in each capacitor in the plurality of capacitors, the second capacitor electrode is conductively connected to the other one of the respective first capacitor contact structure and the respective second capacitor contact structure at a connection location adjacent to a second end of the at least one electrically conductive vertical nanostructure.

9. The image sensor according to claim 1, wherein each capacitor in the plurality of capacitors comprises a plurality of electrically conductive vertical nanostructures, each being electrically conductively connected to one of the respective first capacitor contact structure and the respective second capacitor contact structure, and conductively separated from the other one of the respective first capacitor contact structure and the respective second capacitor contact structure by the layer of the second dielectric material.

10. The image sensor according to claim 9, wherein, for each capacitor in the plurality of capacitors:
a space between neighboring nanostructures in the plurality of electrically conductive vertical nanostructures is filled with electrically conductive material.

11. The image sensor according to claim 9, wherein, for each capacitor in the plurality of capacitors:
a space between neighboring nanostructures in the plurality of electrically conductive vertical nanostructures is at least partly filled with dielectric material.

12. The image sensor according to claim 1, wherein each capacitor in the plurality of capacitors exhibits a capacitance density of at least 200 fF/μm².

13. The image sensor according to claim 1, wherein each capacitor in the plurality of capacitors exhibits a capacitance of at least 200 fF.

14. The image sensor according to claim 1, wherein:
the capacitor layer comprises a plurality of capacitor layer bottom contact pads at a bottom of the capacitor layer; and
each second capacitor contact structure in the plurality of second capacitor contact structures constitutes a respective capacitor layer bottom contact pad in the plurality of capacitor layer bottom contact pads.

15. The image sensor according to claim 14, further comprising a signal processing layer having:
a plurality of signal processing layer contact pads, each being bonded to a respective capacitor layer bottom contact pad in the plurality of capacitor layer bottom contact pads; and
signal processing circuitry coupled to the signal processing layer contact pads.

16. The image sensor according to claim 15, wherein:
the signal processing layer comprises a plurality of signal processing layer bottom contact pads at a bottom of the signal processing layer; and
the image sensor further comprises a functional layer having:
a plurality of functional layer contact pads, each being bonded to a respective signal processing layer bottom contact pad in the plurality of signal processing layer bottom contact pads; and
functional circuitry coupled to the functional layer contact pads.

17. The image sensor according to claim 16, wherein the functional circuitry includes at least one of RF-circuitry, memory circuitry, and sensing circuitry.

18. An electronic device comprising:
processing circuitry for controlling operation of the electronic device; and
an image sensor according to claim 1, coupled to the processing circuitry.

19. The electronic device according to claim 18, wherein the electronic device is one of a mobile phone; an entertainment unit; a navigation device; a communications device; a fixed location data unit; a mobile location data unit; a global positioning system (GPS) device; a smart watch; a wearable computing device; a tablet; a server; a computer; a portable computer; a mobile computing device; a digital camera; CCD camera; a battery charger; a USB device; a desktop computer; a personal digital assistant (PDA); a monitor; a computer monitor; an ADAS; a television; a tuner; a radio; a satellite radio; a music player; a digital music player; a portable music player; a digital video player; an automobile; an electric vehicle; a vehicle component; avionics systems; a drone; and a multicopter.

20. A method of manufacturing a capacitor layer for an image sensor, comprising the steps of:
providing a substrate having a first plurality of discrete conductive material islands thereon;
providing, on each discrete conductive material island in the first plurality of discrete conductive material islands, at least one electrically conductive nanostructure in such a way that the electrically conductive nanostructure extends substantially vertically from the discrete conductive material island and a first end of the electrically conductive nanostructure is in electrically conductive contact with the discrete conductive material island;
applying a conformal dielectric layer on the electrically conductive nanostructures provided on the discrete conductive material islands;
applying a conductive material layer on the conformal dielectric layer, to form a plurality of capacitors each including at least one electrically conductive nanostructure, the conformal dielectric layer and the conductive material layer;
embedding the plurality of capacitors in a dielectric material;
forming a second plurality of discrete conductive material islands, in such a way that each discrete conductive material island in the second plurality of discrete conductive material islands makes electrically conductive contact with the conductive material layer on the at least one electrically conductive nanostructure provided on a respective one of the discrete conductive material islands in the first plurality of discrete conductive material islands; and
removing the substrate.

21. The method according to claim 20, wherein:
the step of forming the second plurality of discrete conductive material islands is performed before the step of embedding the plurality of capacitors in the dielectric material; and
the method further comprises the step of planarizing the dielectric material embedding the plurality of capacitors until the discrete conductive material islands in the second plurality of discrete conductive material islands are exposed.

22. The method according to claim 20, wherein:
the method further comprises the step of planarizing the dielectric material embedding the plurality of capacitors until the conductive material layer on the at least one electrically conductive nanostructure provided on a respective one of the discrete conductive material islands in the first plurality of discrete conductive material islands is exposed; and
the step of forming the second plurality of discrete conductive material islands is carried out after the step of planarizing the dielectric material.

23. The method according to claim 20, wherein the step of applying the conductive material layer on the conformal dielectric layer comprises the steps of:
applying a conformal first conductive material layer directly on the conformal dielectric layer; and
applying a second conductive material layer directly on the conformal first conductive material layer.
